(19) United States
(12) Patent Application Publication
(10) Pub. No.: US 2008/0291322 A1
(43) Pub. Date: Nov. 27, 2008

(54) Method for the Optical Adjustment of a Camerafield of the Invention

(76) Inventor: Jens Schick, Herrenberg (DE)

Correspondence Address: KENYON & KENYON LLP, ONE BROADWAY, NEW YORK, NY, 10004, US

(21) Appl. No.: 11/884,500

(22) PCT Filed: Feb. 8, 2006
(86) PCT No.: PCT/EP2006/050765

§ 371 Date: Apr. 4, 2008

(30) Foreign Application Priority Data
Feb. 15, 2005 (DE) 10 2005 006 755.7

(51) Int. Cl. H04N 5/225; H05K 13/04

(52) U.S. Cl. 348/374; 29/729; 348/E05.024

(57) ABSTRACT

During the assembly of cameras, especially for cameras having imaging optical systems with reduced depth of field, an accurate adjustment of an optical sensor medium relative to the imaging optical system may be necessary. Therefore, a method is provided for optically adjusting a camera in which at least one plastically deformable adjustment element is employed that is plastically deformable by the action of at least one force and/or at least one torque. By deforming this adjustment element, it is possible to alter a placement and/or alignment of the optical sensor medium relative to the imaging optical system so that an optimal image quality is ensured. Because of the stability of the method and the low costs associated with it, the method proposed is also suitable for a serial application.

### FIELD OF THE INVENTION

The present invention relates to a simple and robust method for the optical adjustment of a camera which can be used during or after a manufacturing process of the camera.

### BACKGROUND INFORMATION

Cameras, especially digital cameras, which as a rule have imaging optics and an optical sensor medium, must be adjusted during or after assembly of the individual components. During this adjustment, the relative position or alignment between the imaging optics and the optical sensor medium is set in such a way that the imaging optics project an image which is sharp and not tilted or distorted onto the sensor medium.

In many cameras, especially digital cameras, objectives having a small focal ratio and, correspondingly, a small depth of field, are used. During their production, such cameras are subject to high demands with regard to the adjustment of the objectives relative to the respective optical sensor medium, e.g., an imager. In series production, deviations from design dimensions occur repeatedly, e.g., as the result of tolerances during the production of lenses of the objectives, during the mounting of the objectives relative to a camera housing, during the assembly of a camera housing with cover, when mounting a printed circuit board in the camera housing or on the cover, when installing a sensor medium on a printed circuit board and during the production of a photosensitive surface (e.g., a photosensitive silicon chip) within the sensor medium. As a rule, these tolerances necessitate a subsequent adjustment of the objectives relative to the sensor medium (or vice versa).

Therefore, cameras are often produced in which the relative placement and/or the relative alignment of the objectives with respect to the sensor medium can be adjusted or altered. In this context, usually the sensor medium is disposed in the camera in such a way that the sensor medium may be shifted perpendicular to an optical axis of the camera or twisted, e.g., with the aid of suitable linear guideways or a thread. As a rule, the distance between the sensor medium and the objective is adjusted by a thread on the objective, whereby the objective is able to be positioned along the optical axis of the camera.

However, these methods known from the related art have the disadvantage that it is not possible to compensate for tolerances in all dimensions. In particular, as a rule it is not possible to compensate for so-called wobble angles, that is, tilting of the sensor medium about an axis perpendicular to the optical axis. Because of tolerances from the standpoint of production engineering, however, usually a relative alignment of the sensor medium and objective is necessary in all six degrees of freedom.

Often in conventional methods, (for example, six-axis) positioning systems are also used which position the sensor medium relative to the objective or vice versa. Positioning systems of this kind are complicated and costly, and therefore in many cases are unprofitable, particularly for low-cost cameras. Moreover, there is frequently the problem that, as a rule, the camera has a camera housing which protects optical and electrical components of the camera from mechanical or environmental influences. However, the adjustment methods using (e.g., six-axis) positioning systems known from the related art generally have the disadvantage that the housing of the camera must be opened for the adjustment. In many cases, these openings in the housing (e.g., gaps) remain after the adjustment as well, and accordingly, must be closed later, e.g., by suitable screw connections, form-fitting filler constructions or other methods. However, such subsequent modifications make these methods additionally cost-intensive and complicated from the standpoint of process engineering.

### SUMMARY OF THE INVENTION

Therefore, a method is provided for the optical adjustment of a camera having at least one imaging optical system and at least one optical sensor medium, as well as a camera usable for this method, which avoid the disadvantages described in the related art. The exemplary embodiment and/or exemplary method of the present invention involves a camera which is used and which has at least one plastically deformable adjustment element that is able to be plastically deformed by the action of at least one force and/or at least one torque Due to this plastic deformation, a relative placement and/or a relative alignment of the at least one imaging optical system and the at least one optical sensor medium may be attained in several or all six degrees of freedom. For example, the plastically deformable adjustment element may have at least one length-alteration element deformable parallel to an optical axis of the camera, or other adjustment elements able to be deformed or tilted.

The method for the adjustment of the camera may be developed in various ways. For example, in the method, a relative setpoint placement and/or a relative setpoint alignment between the at least one imaging optical system and the at least one sensor medium may be determined by positioning the at least one sensor medium in such a way that a test pattern is optimally imaged on the sensor medium. The at least one adjustment element of the camera is plastically deformed in such a way that the at least one sensor element retains this relative setpoint placement and/or a relative setpoint alignment even when the camera housing is closed.

### BRIEF DESCRIPTION OF THE DRAWINGS

FIG. 1A shows a perspective representation of a first exemplary embodiment of a camera housing having squeeze columns as adjustment elements.

FIG. 1B shows a top view of the camera housing according to FIG. 1A.

FIG. 1C shows a long-side view of the camera housing according to FIG. 1A.

FIG. 1D shows an end-face view of the camera housing according to FIG. 1A.

FIG. 1E shows a detail view of area A in FIG. 1B.

FIG. 2A shows a perspective representation of a camera cover of the first exemplary embodiment of a camera.

FIG. 2B shows a top view of the camera cover according to FIG. 2A.

FIG. 2C shows a long-side view of the camera cover according to FIG. 2A having fitted imager board.

FIG. 2D shows an end-face view of the camera cover according to FIG. 2A having fitted imager board.

FIG. 2E shows a detail view of area C in FIG. 2C.

FIG. 3 shows a schematic flowchart of a method according to the present invention for the adjustment of a camera.

FIG. 4 shows a schematic flowchart of a method according to the present invention for the adjustment of a camera as an alternative to FIG. 3.

FIG. 5A shows a sectional view of a second exemplary embodiment of a camera according to the present invention having a plastically deformable cover.

FIG. 5B shows a top view of the plastically deformable cover of the camera according to FIG. 5A.

FIG. 6 shows a schematic flowchart of an exemplary embodiment of a method for the adjustment of a camera as an alternative to the methods according to FIG. 3 and FIG. 4.

### DETAILED DESCRIPTION

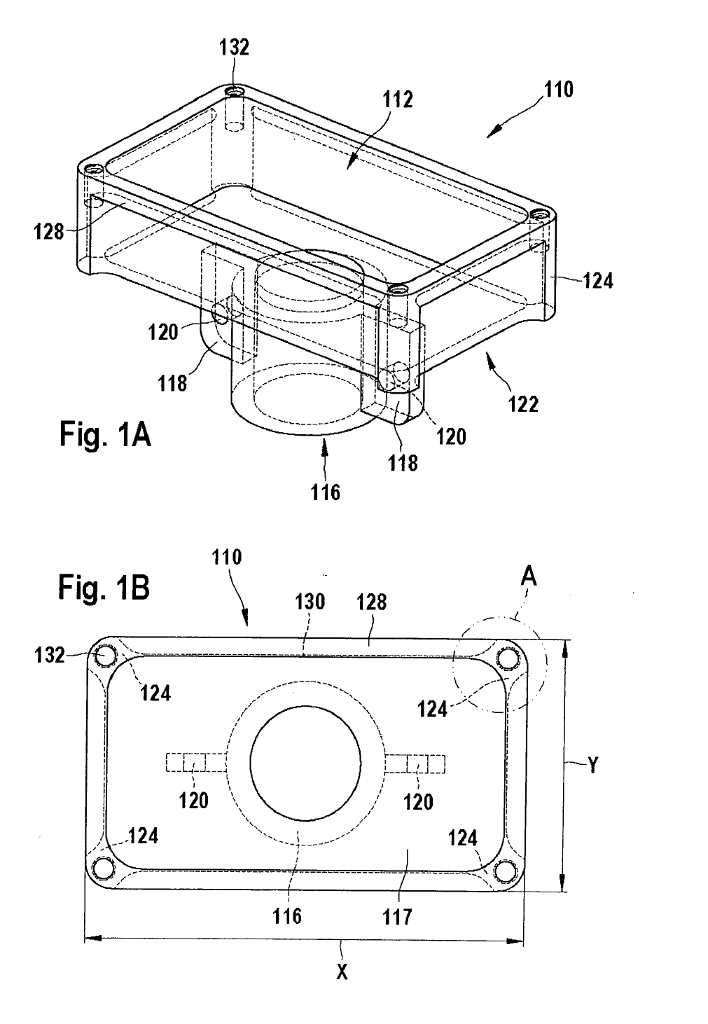

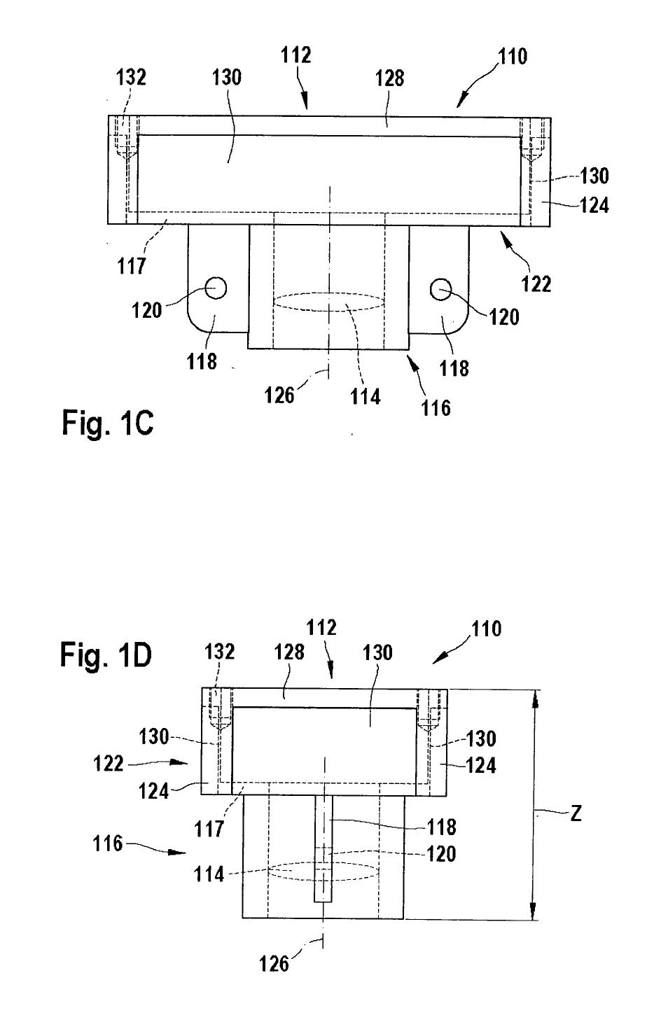

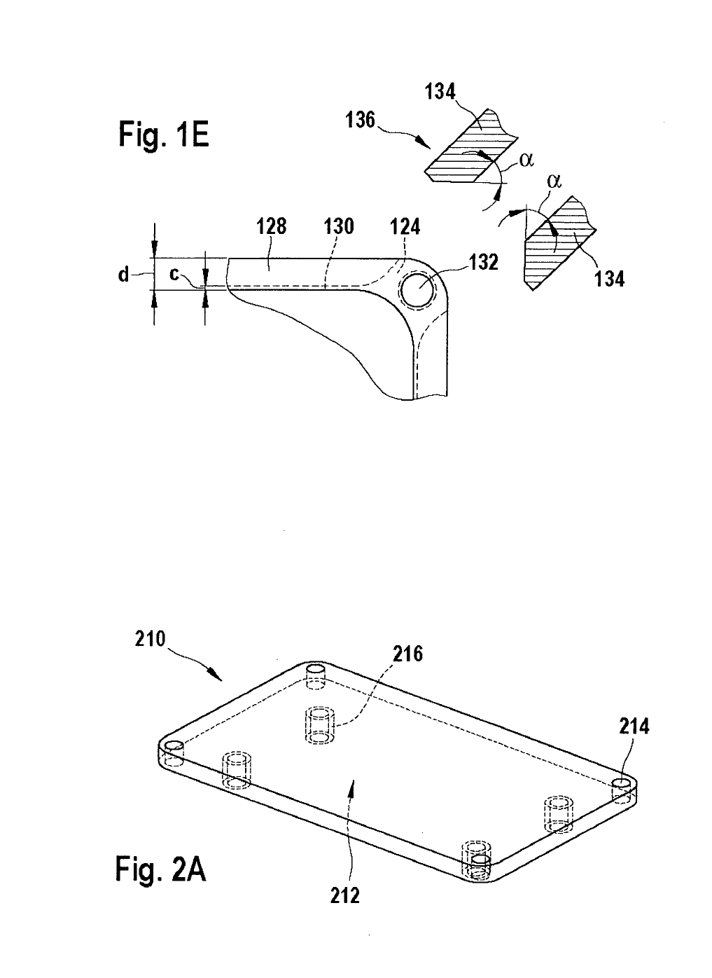

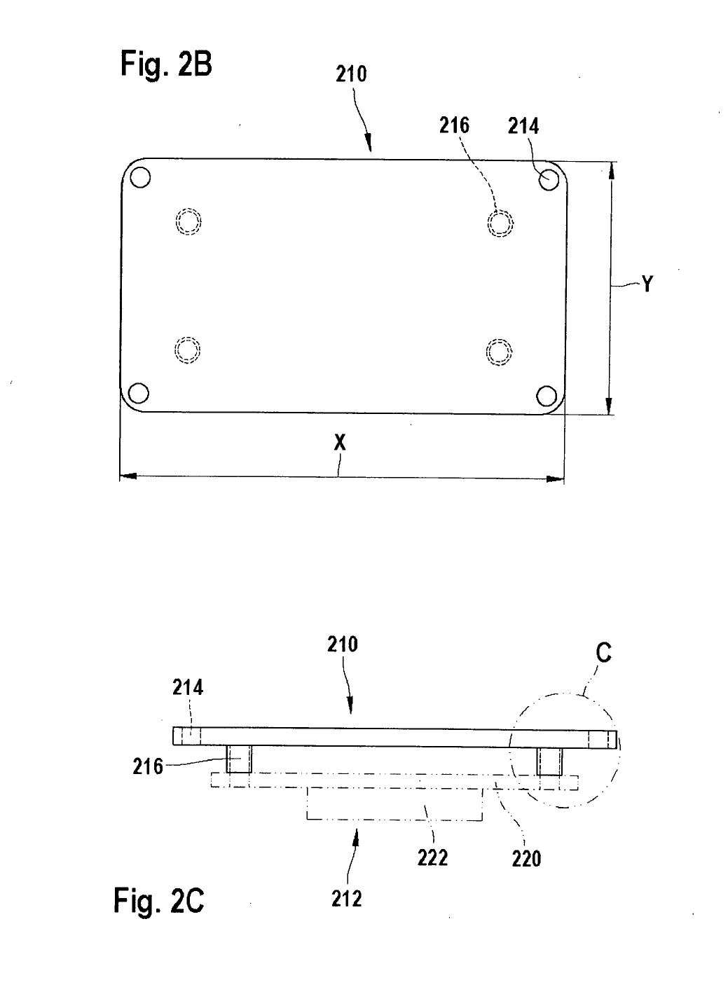

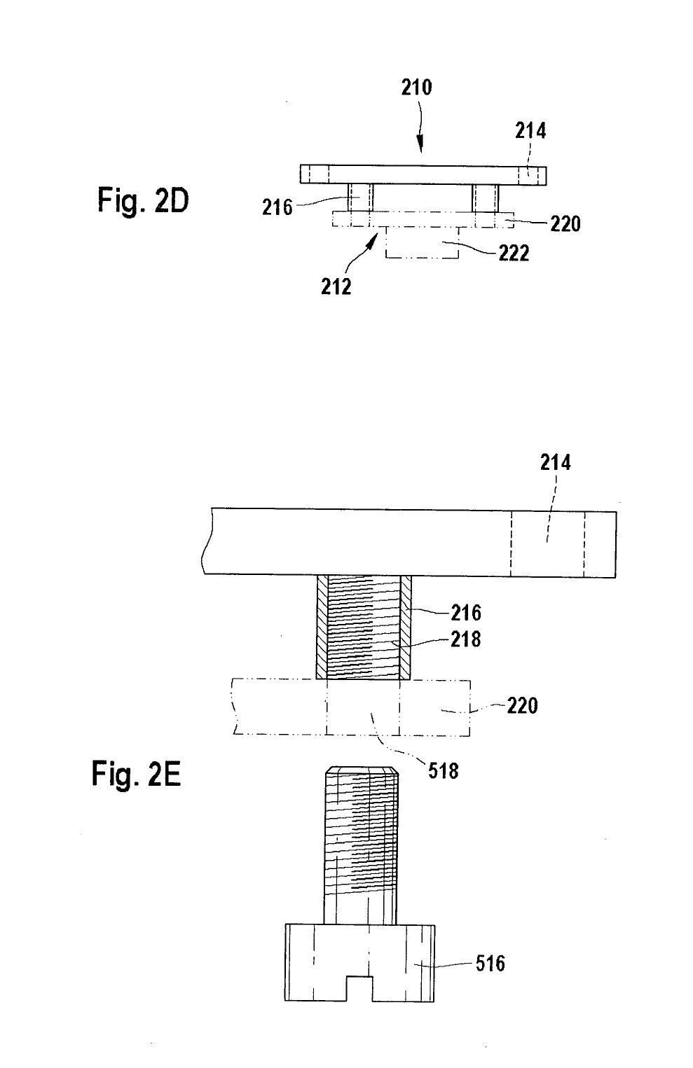

Components of a first specific embodiment of a camera according to the present invention are shown in FIGS. 1A through 1E and 2A through 2E. FIGS. 1A through 1E show a camera housing 110 in various views, while FIGS. 2A through 2E show a camera cover 210 in various views. For example, the camera housing may have aluminum as material. To assemble the camera, camera cover 210 is mounted with its side 212 facing the camera onto open side 112 of camera housing 110.

As shown schematically in FIGS. 1C and 1D, camera housing 110 has an imaging optical system 114. In this illustration, imaging optical system 114 is shown as a single lens 114. However, it may also be a more complex lens system or a combination of lenses and other optical elements such as diaphragms. Imaging optical system 114 is installed in an objective tube 116 of camera housing 110, and is fixed in position there (for example, by clamping, fastening by screws or adhesive). Objective tube 116 is mounted on a base plate 117 of camera housing 110. In so doing, imaging optical system 114 does not necessarily have to be aligned optimally and precisely relative to camera housing 110, so long as no great blockages or substantial image distortions occur. Objective tube 116 has two mountings 118 which stabilize objective tube 116 relative to remaining camera housing 110 and which make it possible to clamp camera housing 110 in a clamping device (not shown), e.g., by screwing mountings 118 to the clamping device via two bores 120 sunk into mountings 118. With the aid of the clamping device, camera housing 110 is able to be adjusted in a predefined or known position relative to a target which, for example, has a test pattern (see below).

Camera housing 110 also has a housing member 122. Housing member 122 essentially has the shape of a right parallelepiped and is provided at four edges with four squeeze columns 124 that run parallel to an optical axis 126. On open side 112 of camera housing 110, squeeze columns 124 lead into a thickened housing flange 128. In this exemplary embodiment, this housing flange 128 has a width d of 2 mm, and allows a substantially media-impervious (that is, for example, impervious to moisture or spray water) mounting of camera cover 210 on housing flange 128. On the other hand, side walls 130 between squeeze columns 124 have a considerably reduced thickness c of only 0.2 mm in this exemplary embodiment. All in all, the camera in this exemplary embodiment has dimensions of approximately X×Y×Z=48×28×26 mm.

Moreover, from open side 112, four tapped bores 132 are sunk into squeeze columns 124 of camera housing 110 (bore direction parallel to squeeze columns 124). Camera cover 210 (see, for example, FIGS. 2A through 2E), which has corresponding bores 214, may be screw-fitted to camera housing 110 via these tapped bores 132.

Camera cover 210, on its side 212 facing the camera, also has four board sockets 216 having tapped bores 218, via which an imager board 220 (indicated by a dot-dash line in FIGS. 2C through 2E), having an imager 222 mounted on it, is able to be screw-fitted to camera cover 210. For example, this imager 222 may be a CCD- or CMOS-Chip which is able to receive image information with the aid of a one-dimensional or two-dimensional image-point (pixel) array and store it. Imager 222 therefore represents an optical sensor medium. Imager 222 should be mounted on imager board 220 in a manner as free of stress as possible, and the mounting should be such that thermal stresses between imager 222 and imager board 220 are also equalized. In particular, joining imager board 220 to camera cover 210 by a screw coupling via board sockets 216 has the advantage that, because of the resilient action of imager board 220, plug-in stresses during the electrical contacting of imager 222 with the aid of a plug connector (not shown) are offset and are not transferred to either imager 222 or camera cover 210. The electrical contacting therefore does not lead to a misalignment.

Squeeze columns 124 of camera housing 110 function in this exemplary embodiment as adjustment elements. The dimensions of camera housing 110 may be changed in a controlled manner via a plastic deformation of squeeze columns 124, whereby a relative placement (i.e., especially a relative position) and/or a relative alignment (i.e., especially a relative tilting) of imaging optical system 114 relative to imager 222 may be changed. In general, adjustment elements 124, that is, in this case, squeeze columns 124, may be selected in such a way that all six degrees of freedom (three shifts and three tiltings) may be adapted by a deformation of camera housing 110 or of camera cover 210. Adaptation with regard to a smaller number of degrees of freedom, e.g., only with regard to height Z of camera housing 110 or with regard to an angle of a tilt about an axis perpendicular to optical axis 126 (about a predefined wobble angle) is also possible. Further degrees of freedom may be adapted by a relative shift of camera cover 210 with respect to camera housing 110 or by a suitable twisting of camera cover 210 relative to camera housing 110 (e.g., about optical axis 126). Instead of simple bores 214 in cover 210, elongated holes may then also be used, for instance, or camera cover 210 and camera housing 110 may be joined by suitable caulking.

In the embodiment of the adjustment elements in the form of squeeze columns 124 shown in FIGS. 1A through 1E, the vertical degrees of freedom (vertical shift and two wobble angles) are adapted by deformation of squeeze columns 124, a shift in a plane perpendicular to optical axis 126 by a shift of housing cover 210 relative to camera housing 110 with subsequent suitable fixation of housing cover 210, e.g., by screw-fitting or caulking. The length of squeeze columns 124 may be changed in particular in that squeeze columns 124, indicated symbolically in FIG. 1E, are grasped by two jaws 134 which, at their tip, are bent about an angle α, which may be 45°. Jaws 134 of the tongs are subsequently pressed together, whereby squeeze columns 124 are squeezed together and thereby elongated. Squeeze columns 124 may be squeezed together simultaneously at all four squeeze columns 124, which means given uniform elongation, a uniform change of height Z of camera housing 110 takes place; or it is possible to elongate only individual squeeze columns 124, whereby in particular a tilting of the surface of housing flange 128 (and therefore of camera cover 210) relative to base plate 117 of camera housing 110 takes place. The embodiment according to FIGS. 1A through 1E, in which side walls 130 are kept very thin (thickness c=0.2 mm in comparison to thickness d of housing flange 128 of 2 mm), has the advantage that the resistance of side walls 130 to the elongation of squeeze columns 124 is very low. In order to later protect thin side walls 130 of camera housing 110, after the adjustment has been carried out, an additional plastic casing may be slipped over the housing sides of camera housing 110. The resistance of side walls 130 may be further minimized by previous bulging of side walls 130.

In addition to a simple elongation of squeeze columns 124, squeeze columns 124 may also be tilted, camera cover 210 thereby being shifted in a plane perpendicular to optical axis 126 relative to base plate 117. In order to tilt squeeze columns 124, for instance, two tongs 136, each having two tong jaws 134, may be placed one above the other perpendicular to the drawing plane in FIG. 1E. Tongs 136 in each case grasp one squeeze column 124 with their tong jaws 134 displaceable in parallel to each other. If the two tongs 136 are now shifted relative to each other, e.g., in the drawing plane according to FIG. 1E, squeeze column 124 is tilted and, at the same time, likewise plastically deformed. For example, lower tongs 136 may be held constant in its position, whereas upper tongs 136 is shifted in the drawing plane according to FIG. 1E. In this way, using tongs 136 shown, it is possible to both elongate and tilt squeeze columns 124 by squeezing jaws 134 together. Both the elongation of squeeze columns 124 and the tilting may be measured by suitable measuring devices, e.g., by measuring heads or optical measuring devices which, for example, may be integrated into a handling (robot) system, and the deformation (elongation or tilting) may be controlled appropriately by using a suitable arithmetic-logic unit to drive tongs 136.

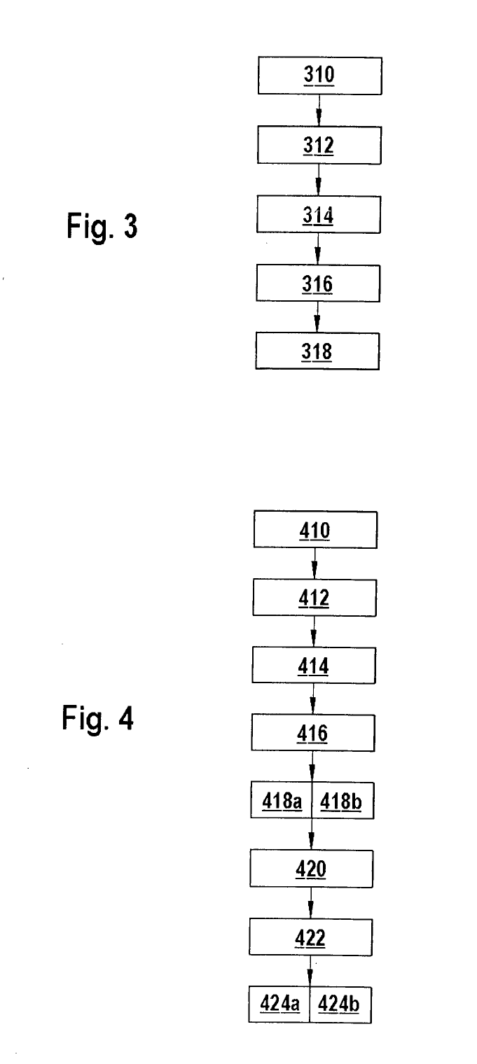

For example, with a camera having a housing 110 according to FIGS. 1A through 1E and a camera cover 210 according to FIGS. 2A through 2E, several alternative or mutually complementing methods for adjusting imager 222 relative to imaging optical system 114 may be carried out in the exemplary embodiment and/or exemplary method of the present invention. Two flow charts of suitable examples of methods according to the present invention are shown schematically in FIGS. 3 and 4; the method steps shown do not necessarily have to be carried out in the order illustrated. Additional method steps not shown in FIGS. 3 and 4 may also be carried out. FIG. 3 represents a first embodiment variant of a method according to the present invention; FIG. 4 represents a second and third alternative embodiment variant. Optimally, in all three embodiment variants, one starts with a camera housing 110 having a height Z that is somewhat less than the height actually needed later on, so that the necessary adjustment may be made by elongating squeeze columns 124.

In the method according to FIG. 3, first of all camera housing 110 is fixed in position relative to a predefined target, e.g., a test pattern (see below) using a clamping device (method step 310). At the same time, camera cover 210 is grasped by a handling system and, with its side 212 facing the camera, is moved toward housing flange 128 of camera housing 110. In this context, the handling system may in particular have a measuring device for determining a position and/or alignment of camera cover 210. The position and/or alignment of camera cover 210 in which it is resting flat on housing flange 128 of camera housing 110 is defined as zero position of the handling system (method step 312). Subsequently in method step 314, camera cover 210, together with fitted imager board 220, is positioned spatially (by suitable translation and rotation) by the handling system in such a way that the target is imaged optimally (that is, with maximum sharpness and in optimum position) by imaging optical system 114 onto imager 222. For example, this may be accomplished using suitable control electronics, by which the image quality of an imaging on imager 222 is optimized by suitable shifting and/or tilting of camera cover 210. Subsequently, in method step 316, camera housing 110 is deformed in such a way, especially by suitable elongation of squeeze columns 124, that housing flange 128 abuts in parallel fashion against camera cover 210. Finally, in method step 318, camera cover 210 is joined to camera housing 110, e.g., by a screw connection or bonding.

FIG. 4 shows a further exemplary embodiment for the adjustment of a camera which, in turn, may be carried out in two slightly different variants. These two alternative embodiments of the method differ only in the procedure for the compensation of an offset in a plane perpendicular to optical axis 126.

In both specific embodiments, camera housing 110 is again first grasped by a suitable clamping device and fixed in position so that it is aligned with respect to a target (method step 410). Subsequently in method step 412, camera cover 210 is preassembled on camera housing 110, e.g., by temporarily putting camera cover 210 onto camera housing 110. In method step 414, camera cover 210 is subsequently grasped by a handling system, this position or alignment of the handling system being defined as zero position. Analogous to method step 314 in the exemplary embodiment according to FIG. 3, in method step 416, camera cover 210 is then positioned or aligned by the handling system in such a way that the target is optimally imaged through imaging optical system 114 onto imager 222. In so doing, suitable control electronics may again be used. As a rule, during this positioning or alignment, among other things, camera cover 210 is also shifted in a plane perpendicular to optical axis 126 (plane offset).

Subsequently, camera cover 210 is again positioned by the handling system onto housing flange 128 of camera housing 110. In doing this, however, two method variants are possible. In a first method variant (method step 418a), the handling system does indeed again move camera cover 210 toward the camera housing, however the above-described plane offset of the shift in a plane perpendicular to optical axis 126 is maintained. In comparison to the previous zero position, camera cover 210 thus now rests on camera housing 110 in displaced fashion. Alternatively, the handling system can also move camera cover 210 completely into the zero position again (method step 418b), the plane offset thus being canceled again as well. Subsequently (in both method variants), camera cover 210 is secured to camera housing 110 (method step 420), e.g., by screw connection, caulking or bonding. In so doing, in the method variant according to FIG. 418a, it should be ensured in particular that bores 214 in camera cover 210 are of sufficient size to also make it possible to screw camera cover 210 to camera housing 110, while maintaining the plane offset. The use of elongated holes is also possible.

In method step 422, the handling system is subsequently switched to the driveless state, that is, the handling system may now be used as a pure measuring device by which it is possible to determine the position or alignment of camera cover 210. Subsequently, camera housing 110 is suitably deformed by squeezing in order to return imager 222 or camera cover 210 to the relative position determined as optimal in method step 416. The two alternative embodiments of the method according to FIG. 4 differ again in this method step. Since the desired plane offset was maintained in method step 418a, in this embodiment of the method, squeeze columns 124 of camera housing 110 only have to be elongated by squeezing (as described above) until camera cover 210 is again in its optimal relative position (method step 424a). It is not necessary to tilt squeeze columns 124 in this embodiment of the method. On the other hand, if, as in method step 418b, the plane offset was not maintained, then in this embodiment, in addition to elongating squeeze columns 124, it is now also necessary to tilt squeeze columns 124 (method step 424b) in order to return camera cover 210 to its optimal relative position again. For example, this elongation and tilting may be accomplished according to the method described above using two tongs 136, situated one above the other, per squeeze column 124.

The method of the present invention has several advantages compared to conventional methods. In particular, it is possible for the camera to have only two main components, camera housing 110 and camera cover 210. After the adjustment, both components 110, 210 lie flat one upon the other, so that a seal may easily be implemented between both components 110, 210 (e.g., by sealing rings). Moreover, imager board 220 is fixedly mounted on camera cover 210, so that distortions (twisting) of imager board 220 due to subsequent manufacturing steps are avoided, and heat may be dissipated from imager board 220 via camera cover 210. Furthermore, additional materials which can lead to thermal distortions and deformations are not necessarily required in the production, so that the construction is easy to simulate (e.g., by finite-element methods). It is also possible to dispense with materials which make time-consuming processing necessary, especially drying, heat treatment, curing, etc., or which are otherwise difficult to handle, e.g., adhesives. In the event camera housing 110 is unsuccessfully deformed, camera cover 210 can continue to be used immediately, and the camera housing can be returned to the production process again by reverse strain. Material waste is thus reduced considerably, making the method very favorable from the standpoint of expense.

In many cases, the materials used, e.g., the material or materials used for squeeze columns 124 of camera housing 110, do not have purely plastic properties, but also have an elastic component. Consequently, an action of force on camera housing 110 also leads to a reversible elastic deformation, which is canceled again after the acting force is terminated. In this connection, however, in many cases the problem occurs that a handling system, which is intended merely to measure a position or alignment, exerts a force on camera housing 110 or camera cover 210 even in this driveless switching operation. Accordingly, camera housing 110 or camera cover 210 is elastically deformed, this deformation being canceled again after removal of the load. After removal of the handling system, a change in the respective actual position or alignment will come about due to the deformation of housing 110 or of camera cover 210. According to the present invention, this disadvantage can be offset by additionally using a measuring device which, in contactless fashion, determines the position or alignment of camera cover 210 in its optimal relative position. For example, optical measuring devices may be used in this connection. Upon deformation of camera housing 110, the position or alignment of camera cover 210 is again measured in contactless fashion until this position or alignment agrees again with the optimal (i.e., main setpoint) position or alignment determined before.

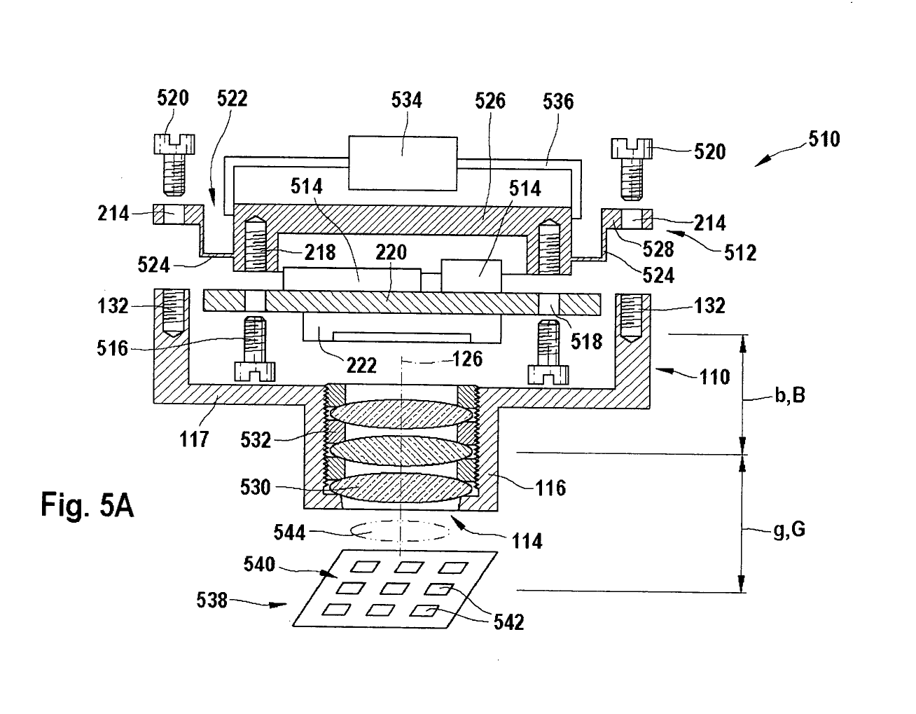

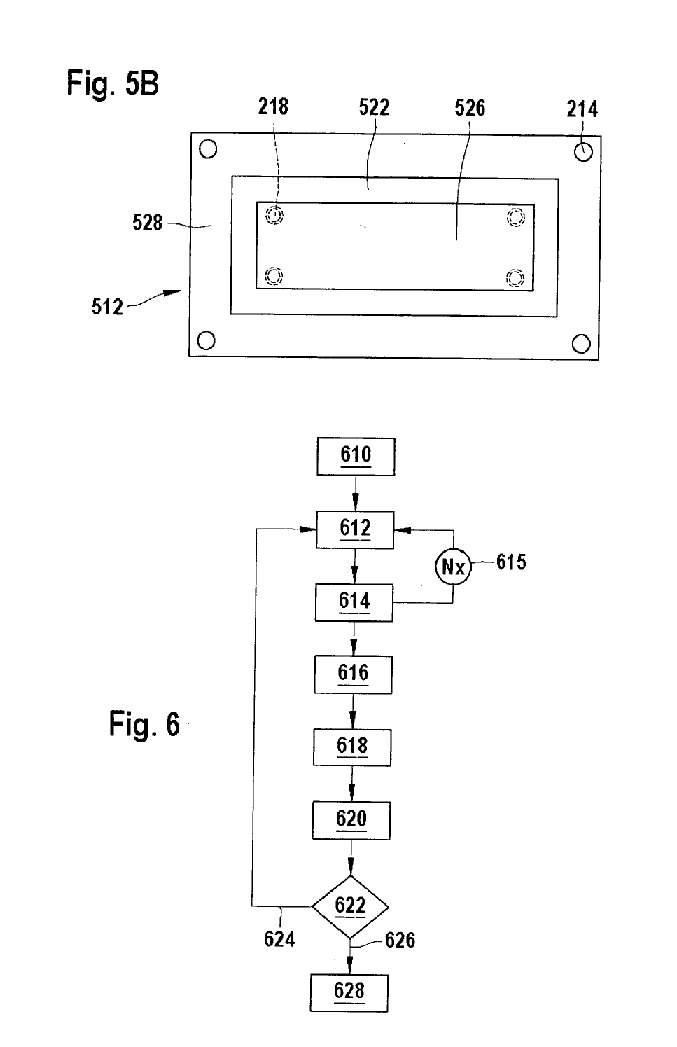

FIG. 5A shows a second exemplary embodiment of a camera 510 according to the present invention in which a plastically deformable camera cover 512 is used as adjustment element. FIG. 5B shows this plastically deformable camera cover 512 in a plan view, thus, the camera cover in FIG. 5A in a view from above. Camera 510 again has a camera housing 110 having a base plate 117, an imaging optical system 114 fitted into an objective tube 116, a camera cover 512 (plastically deformable in this exemplary embodiment), as well as an imager board 220 having an imager 222. In addition, disposed on imager board 222 (as also in the first exemplary embodiment, not shown there in FIGS. 2C and 2D) are further electronic components 514, which, for example, may be voltage supplies, storage elements, signal processing elements (e.g., digital signal processors, DSPs) or similar components. Again not shown in FIG. 5A is a contacting of imager board 220, via which image information of imager 222 may be accessed from outside, and via which, for example, imager 222 and electronic components 514 may also be supplied with energy.

In this exemplary embodiment, as also in the first exemplary embodiment, imager board 220 is again screw-fitted to camera cover 512 with the aid of screws 516, corresponding bores 518 in imager board 220 and tapped bores 218 in camera cover 512. Camera cover 512 is screw-fitted to camera housing 110 by screws 520 through bores 214 and tapped bores 132.

Moreover, in this exemplary embodiment, camera cover 512 has a weakening in the form of a groove 522 having a rectangular profile and thin groove walls 524 compared to the remaining thickness of camera cover 512. Camera cover 512 has a plastically deformable material which ideally exhibits no elastic deformational behavior. In this context, the weakening of camera cover 512 in the form of groove 522 is disposed in such a way that rectangular groove 522 encompasses a massive central area 526 which exhibits high rigidity. Tapped bores 218 are part of this massive central area 526, so that imager board 220 is joined essentially rigidly to massive central area 526 via screws 516. Bores 214, via which camera cover 512 is screw-fitted to camera housing 110, are located outside of rectangular groove 522 in an outer flange area 528.

The embodiment of camera 510 according to the exemplary embodiment in FIG. 5A permits a placement and/or alignment of imager 222 relative to imaging optical system 114. For this purpose, for example, camera 510 is already completely assembled, imaging optical system 114, which in this exemplary embodiment has three individual lenses 530 as well as corresponding screw holding devices 532, being introduced into objective tube 116. Moreover, camera cover 512, with imager board 222 screwed on (e.g., by screws 520 or also by a temporary preassembly), is joined to camera housing 110. In particular, this joining between camera cover 512 and camera housing 110 may be implemented so that it is already impervious to media, for instance, by introducing a suitable seal between outer flange area 528 of camera cover 512 and housing flange 128. In this manner, especially imager 222 is already protected from environmental influences such as the effect of impurities, spray water or atmospheric humidity. An adjustment of the placement and/or alignment of imager 222 relative to imaging optical system 114 may subsequently be carried out after the assembly in a working environment of which considerably lower demands can be made with respect to cleanliness and atmospheric humidity than in the case of conventional methods. For this adjustment, camera cover 512 is grasped by a suitable handling system 534 having a gripper 536 which grabs into groove 522, for example, and therefore grips massive central area 526. If, as also described in the first exemplary embodiment, camera housing 110 is at the same time firmly clamped in a clamping device, then handling system 534 is able to change the placement and/or alignment of massive central area 526, with imager board 222 screwed on, relative to the imaging optical system by deformation of camera cover 512, thereby permitting an alignment of imager 522 in all six degrees of freedom relative to imaging optical system 114 without impressing great forces. For this purpose, in particular the thickness of groove walls 524 is suitably selected so as to permit easy deformation of camera cover 512 by handling system 534, while still always selecting groove walls 524 to be strong enough to avoid deformations due to slight vibrations of camera 510 during a subsequent handling.

One possible method for adjusting camera 510 is illustrated in FIG. 6, which shall be clarified in combination with FIG. 5A. However, it should be pointed out that the exemplary embodiment of the adjustment method according to FIG. 6 may also be combined with features of the adjustment methods according to FIGS. 3 and 4, and that the exemplary embodiments shown may be applied analogously to other embodiments of the camera, as well. Thus, additional method steps not shown in FIG. 6 may again also be carried out in the method according to FIG. 6 shown, and the method according to FIG. 6 does not necessarily have to be carried out in the sequence shown. The adjustment method according to FIG. 6 is again based on the fact that first of all, camera housing 110 is fixed in position (e.g., by a clamping device) relative to an optical target 538. Optical target 538 has a test pattern 540, which in turn has at least one test mark 542.

Analogous to the adjustment methods described above (see FIGS. 3 and 4), an image of test pattern 540 could now be recorded by imager 222, and subsequently camera cover 512 could be deformed by handling system 534 until an optimal image quality is achieved. In so doing, in particular a control process may be used again, or, for example, also an iterative process again, in which a deformation is implemented while observing the image quality; after the deformation, an equalization of corresponding elastic deformations may take place in a suitable waiting time, followed again by an observation of the image quality with subsequent deformation.

In this way, it is also possible to use materials which exhibit a non-disappearing elastic deformational behavior.

As an alternative to this method, however, an optimal placement (setpoint placement) and/or an optimal alignment (setpoint alignment) of imager 222 relative to imaging optical system 114 may also be determined, e.g., using a suitable calculation algorithm. This is depicted in FIG. 6. For example, this calculation may be carried out by comparing an imaging-sharpness characteristic of an image of test pattern 540 recorded by imager 222 to a known or calculated imaging-sharpness characteristic. This comparison is based on the fact that for a given imaging optical system 114, the relation between an object distance (distance between object and optical system) g and an image distance (distance between image and optical system) b (g and b not necessarily having to be one-dimensional variables—for example, generally a matrix-optical calculation method familiar to one skilled in the art is employed here) is known or is able to be calculated, the characteristic of the imaging sharpness (depth of field) also being known or being able to be calculated.

This means in particular that it is known how image distance b, thus, in particular, the optimal distance between imaging optical system 114 and imager 222, is altered in response to a change of object distance g, thus a distance g of test pattern 540 from imaging optical system 114 (or a corresponding virtual lens which combines the optical properties of imaging optical system 114). Naturally, an observation of this kind is to be carried out in all dimensions and for all image points of imager 222, so that not only a simple distance is determined, but also a shift and tilting. Alternatively or additionally, it is also known how the image sharpness of the image recorded by imager 222 changes when object distance g is altered, while the position and/or alignment of the imager is constant. Based on this information, it is possible to generate a suitable algorithm for calculating a setpoint placement or setpoint alignment of imager 222 relative to imaging optical system 114.

In the ideal case, given a predefined setpoint alignment G of test pattern 540 relative to imaging optical system 114 and a setpoint placement and setpoint alignment B of imager 222 relative to imaging optical system 114, camera 510 supplies an optimal image. The method is now based on the following steps: given a present placement and/or alignment, to in each case record an image; to determine its sharpness (i.e., sharpness distribution over the image area); to then alter arrangement g of test pattern 540; to subsequently again record an image; and based on the change in image quality, to finally calculate a setpoint placement and setpoint alignment of imager 222 relative to imaging optical system 114. For an ideally typical optical system without image curvature, generally three such measurements are sufficient to calculate a setpoint placement and setpoint alignment of imager 222 relative to imaging optical system 114. If, in addition, image curvatures occur, then more measuring points are necessary accordingly.

Various methods are possible for performing these measurements. So, for example, a single test mark 542 may be shifted spatially in front of camera 510, images being recorded in various known positions. A test mark 542 may also be shifted spatially until the imaging of this test mark 542 on imager 222 has achieved optimal sharpness. Based on this, (at least in one dimension) a necessary shift of imager 222 relative to imaging optical system 114 may then be calculated, so that given a setpoint placement G of test mark 542, an optimal image is obtained on imager 222. If three test marks 542′ are shifted, then, in addition to a necessary translation of imager 222 relative to imaging optical system 114, the necessary settings for the wobble angles, thus, for tiltings in each case about an axis perpendicular to optical axis 126, also result. Based on the position of the imagings of test marks 542 on imager 222, it is then also possible to ascertain the necessary lateral displacement (thus, in a plane perpendicular to optical axis 126 of imager 222) and/or a rotation of imager 222 about optical axis 126. Therefore, it is possible to completely calculate how to position and/or to align imager 222 relative to imaging optical system 114 in order to achieve an optimal adjustment in all six degrees of freedom.

Instead of one test mark 542, it is also possible to use test patterns 540 which are made up of individual test marks 542 in a known spatial arrangement. In this case, test marks 542 situated next to one another in a plane perpendicular to optical axis 126 may be used, thereby making it possible to perform measurements at various points in this plane “simultaneously” using a single imaging. Therefore, from the sharpness of various test marks 542 within test pattern 540, by recording only one image, it is possible to calculate optimal image distance B based on a known sharpness distribution as a function of image distance g.

The sharpness distribution may also be shifted or influenced by an auxiliary optical system 544 between test pattern 540 and imaging optical system 114. Side-by-side test marks 542 may also be imaged onto imager 222 via auxiliary optical systems 544 which are different, but whose properties are known. Moreover, auxiliary optical systems 544 may also be exchanged during the measurement, in order to shift the sharpness distribution of the imaging onto imager 222 using only one test mark 542. Furthermore, in addition to lenses, auxiliary optical system 544 may also have mirror systems in order to image a single test mark 542 onto imager 222 via different lenses or auxiliary optical systems 544. In all these methods, the sharpness distribution or its shift should be known or be able to be calculated.

If the sharpness distribution (depth of field) of the imaging of a test pattern 540 through imaging optical system 114 is not known, it may also be ascertained experimentally. To that end, one test mark 542 or an entire test pattern 540 is moved in its position in front of imaging optical system 114 parallel to optical axis 126. In so doing, imagings are recorded by imager 222 at various distances (i.e., at various object distances g) and their sharpness determined. Thus, it is possible to ascertain a relationship between the image sharpness on imager 222 and object distance g. In addition, it is also possible to use test marks 542 staggered in the direction of optical axis 126, the sharpness distribution being inferred from the known distance of test marks 542 along optical axis 126 and the sharpness of the imaging on imager 222 resulting in each case. For example, three-dimensional arrangements of test marks 542 may be used. Thus, even if the sharpness distribution of imaging optical system 114 is not known, this sharpness distribution may be determined experimentally and then, in turn, a setpoint placement or setpoint alignment B of imager 222 relative to imaging optical system 114 may be inferred from the individual imagings of test pattern 540 on imager 222.

In the method according to FIG. 6, it is assumed that the sharpness distribution of imaging optical system 114 is known. If this is not the case, then as described above, the method is first preceded by a method step in which this sharpness distribution is determined experimentally. In the method according to FIG. 6, camera 510 is first of all fixed in position relative to target 538 (e.g., using a suitable clamping device), imaging optical system 114 already being integrated into camera housing 110, and camera cover 512 with fitted imager board 222 already being screw-fitted (e.g., imperviously) to camera housing 110 (method step 610). Target 538 is positioned in a known position in front of imaging optical system 114 (method step 612). Subsequently in method step 614, an imaging of test pattern 540 on imager 222 is recorded. If applicable, this image recording may be repeated with a number of N repetitions (method step 615), target 538 in turn being repositioned (i.e., in a different position) relative to imaging optical system 114 (method step 612), followed by a repeated recording of an image (method step 614). From this image information, with the aid of the known sharpness distribution, a setpoint placement and/or setpoint alignment of imager 222 is subsequently calculated (method step 616), that is, it is calculated how imager 222, starting from its present position and alignment, must be shifted or aligned in order to achieve an optimal adjustment. Thus, shifts and tiltings of imager 222 are able to be calculated in all six degrees of freedom.

Now, with the aid of handling system 534, camera cover 512 is suitably deformed via gripper 536 in order to bring imager 222 into the setpoint placement and/or setpoint alignment calculated beforehand (method step 618). In method step 620, a check measurement is subsequently performed, in the course of which an image of test pattern 540 on imager 222 is again recorded. For this purpose, for example, target 538 having test pattern 540 may be moved into a setpoint position G. In a subsequent assessment step 622, it is analyzed whether camera 510 thus adjusted meets predefined quality requirements with regard to image quality (especially the sharpness or also the alignment of the image). In so doing, for instance, the sharpness of individual image points of the imaging of test pattern 540 on imager 222 may be compared to setpoint values. If it is thereby determined that these values deviate by more than a predefined tolerance threshold from the setpoint values, in method step 624, there is a return to method step 612, so that an image of a test pattern 540 is again recorded in different target positions, and from this in turn a setpoint placement and/or setpoint alignment of imager 222 is calculated. After a repeated deformation of the camera housing in method step 618, in method step 622, an assessment step in which the adjustment is assessed is then carried out again. In this way, the adjustment may be optimized in iterative fashion until predefined quality criteria are achieved.

If it is recognized in assessment step 622 that the adjustment satisfies the requirements, then (method step 626) a stiffening step 628 is initiated. In this stiffening step 628, which represents an optional method step, groove 522 in plastically deformable camera cover 512 is filled in with a filler material. This filler material, which, for example, may be a curing material, additionally stiffens camera cover 512 and prevents unintentional deformations and therefore misalignment of camera cover 512, with imager board 220 screwed onto it, from occurring during subsequent use of camera 510. For example, these filler materials may be materials which cure in response to heating (e.g., in a tempered calibration station at 65° C., for instance). In particular, the filler materials may be plastics, e.g., epoxides.

1-11. (canceled)

12. A method for the optical adjustment of a camera having at least one imaging optical system and at least one optical sensor medium, the method comprising:
setting at least one of a relative setpoint placement and a relative setpoint alignment of the at least one imaging optical system and the at least one optical sensor medium; and
applying at least one of (i) at least one force, and (ii) at least one torque, wherein at least one plastically deformable adjustment element is plastically deformed by the action of the at least one of (i) the at least one force, and (ii) the at least one torque.

13. The method of claim 12, wherein:
the at least one imaging optical system is fixed in at least one of a known spatial position and a known alignment relative to at least one test pattern; and
the at least one optical sensor medium is at least one of positioned and aligned spatially in at least one of a setpoint placement and a setpoint alignment so that the at least one test pattern is optimally imaged on the optical sensor medium.

14. The method of claim 12, wherein at least one of a placement and an alignment of at least one of (i) the at least one imaging optical system, and (ii) the at least one sensor medium are measured, the measurement preferably being performed in contactless fashion.

15. The method of claim 12, wherein:
with at least one sensor medium, at least one imaging of at least one test pattern is recorded with at least one of a present relative placement and a present relative alignment of the at least one imaging optical system and the at least one optical sensor medium; and
at least one of a relative setpoint placement and a relative setpoint alignment between the at least one imaging optical system and the at least one optical sensor medium is determined using a known sharpness distribution.

16. The method of claim 15, wherein the sharpness distribution of the at least one imaging optical system is determined using at least one test pattern.

17. The method of claim 16, wherein the at least one test pattern includes at least one test mark, and wherein at least one auxiliary optical system is used.

18. The method of claim 12, wherein after completion of the adjustment, the camera is additionally stiffened to prevent further plastic deformations.

19. A camera comprising:
at least one imaging optical system;
at least one optical sensor medium; and
at least one plastically deformable adjustment element;
wherein at least one form of the at least one plastically deformable adjustment element determines at least one of a relative placement and a relative alignment of the at least one imaging optical system and the at least one optical sensor medium.

20. The camera of claim 19, wherein the at least one optical sensor medium is fixed in position on a printed circuit board.

21. The camera of claim 19, wherein the camera includes a camera housing and a camera cover, the at least one optical sensor medium being joined either to the camera housing or to the camera cover, and the at least one imaging optical system being joined to the respective other of these elements.

22. The camera of claim 19, wherein the camera includes an optical axis, the at least one plastically deformable adjustment element being deformable so that the at least one optical sensor medium is at least one of (i) able to be shifted at least one of parallel and perpendicular to the optical axis, and (ii) able to be at least one of rotated about the optical axis and tilted about an axis perpendicular to the optical axis.
